(19) United States
(12) Patent Application Publication
(10) Pub. No.: US 2012/0247553 A1
(43) Pub. Date: Oct. 4, 2012

(54) PHOTOVOLTAIC DEVICE WITH BUFFER LAYER

(76) Inventors: Keith J. Burrows, Mineral Point, WI (US); Annette Krisko, Sauk City, WI (US); Boil Pashmakov, Troy, MI (US); Harshad Patil, Madison, WI (US); Yu Yang, Perrysburg, OH (US); Zhibo Zhao, Novi, MI (US)

(21) Appl. No.: 13/430,156

(22) Filed: Mar. 26, 2012

Related U.S. Application Data
(63) Continuation of application No. 13/206,921, filed on Aug. 10, 2011, now abandoned.
Application No. 13/206,921 is a continuation of application No. 12/974,652, filed on Dec. 21, 2010, now abandoned.
(60) Provisional application No. 61/288,765, filed on Dec. 21, 2009.

(51) Int. Cl. H01L 31/0224; H01L 31/18

(52) U.S. Cl. 136/256; 438/98; 257/E31.126

(57) ABSTRACT

A method of manufacturing a structure can include forming a buffer layer on a transparent conductive oxide layer, where the buffer layer includes a layer including zinc and tin, and the transparent conductive oxide layer includes a layer including cadmium and tin.

### CLAIM FOR PRIORITY

This application claims priority under 35 U.S.C. §119(e) to U.S. Provisional Patent Application Ser. No. 61/288,765 filed on Dec. 21, 2009, which is hereby incorporated by reference.

### TECHNICAL FIELD

The present invention relates to photovoltaic devices and methods of production.

### BACKGROUND

Photovoltaic devices can use transparent thin films that are also conductors of electrical charge. The conductive thin films can include transparent conductive layers that contain one or more transparent conductive oxide (TCO) layers. Past photovoltaic devices can be inefficient at converting solar power into electrical power.

### DESCRIPTION OF DRAWINGS

FIG. 1 is a schematic of a structure.

FIG. 2a is a schematic of a structure.

FIG. 2b is a schematic of a structure.

FIG. 3 is a schematic of a photovoltaic device.

### DETAILED DESCRIPTION

Photovoltaic devices can include multiple layers formed on a substrate (or superstate). For example, a photovoltaic device can include a barrier layer, a transparent conductive oxide (TCO) layer, a buffer layer, a semiconductor window layer, and a semiconductor absorber layer, formed in a stack on a substrate. Each layer may in turn include more than one layer or film. For example, the buffer layer can include a first film created (for example, formed or deposited) on the TCO layer and a second film created on the first film. Additionally, each layer can cover all or a portion of the device and/or all or a portion of the layer or substrate underlying the layer For example, a “layer” can mean any amount of any material that contacts all or a portion of a surface.

A buffer layer can include an oxide buffer layer created (for example, formed or deposited) on top of TCO layers to improve the photovoltaic device performance when the buffer layer has the proper transparency, thickness, and conductivity. The buffer layer can be used to decrease the likelihood of irregularities occurring during the following process, and optimize a junction Fermi level. However, a problem with the oxide buffer layer is maintaining its conductivity in an optimal range. Doping with a dopant can help achieve a good conductivity level in the buffer layer. The doped oxide buffer layer can be formed in any suitable manner, including sputtering from a sputter target including the buffer material and the dopant.

In one aspect, a structure can include a substrate, a transparent conductive oxide adjacent to the substrate, and a buffer layer adjacent to the transparent conductive oxide layer. The transparent conductive oxide layer can include cadmium and tin. The buffer layer can include zinc and tin. The buffer layer can have a thickness of about 50 to about 2000 A. The thickness can be about 250 to about 1000 A. The buffer layer can have a tin to zinc ratio that ranges from about 1:100 to about 100:1 by weight. The buffer layer can have a tin to zinc ratio of about 15:85. The buffer layer can include a zinc tin oxide. The buffer layer can include a zinc stannate. The transparent conductive oxide layer can include a cadmium stannate. The substrate can include a glass. The glass can include a soda-lime glass. The glass can include a soda-lime glass with reduced iron content.

In one aspect, the structure can include a bather layer formed between the substrate and the transparent conductive oxide layer. The barrier layer can include silicon oxide, aluminum-doped silicon oxide, boron-doped silicon oxide, phosphorous-doped silicon oxide, silicon nitride, aluminum-doped silicon nitride, boron-doped silicon nitride, phosphorous-doped silicon nitride, silicon oxide-nitride, titanium oxide, niobium oxide, tantalum oxide, aluminum oxide, zirconium oxide, or tin oxide. The structure can include one or more barrier layers on a soda-lime glass substrate. The transparent conductive oxide layer can be positioned on the one or more barrier layers. Each of the one or more barrier layers can include silicon oxide, aluminum-doped silicon oxide, boron-doped silicon oxide, phosphorous-doped silicon oxide, silicon nitride, aluminum-doped silicon nitride, boron-doped silicon nitride, phosphorous-doped silicon nitride, silicon oxide-nitride, titanium oxide, niobium oxide, tantalum oxide, aluminum oxide, zirconium oxide, or tin oxide. The transparent conductive oxide layer can include a cadmium stannate, and the buffer layer can include a zinc tin oxide.

The structure can include a semiconductor window layer adjacent to the buffer layer. The semiconductor window layer can include cadmium sulfide. The semiconductor window layer has a thickness of about 50 to about 500 A. The structure can include a semiconductor absorber layer adjacent to the semiconductor window layer. The semiconductor absorber layer can include cadmium telluride. The structure can include a back contact metal on the semiconductor absorber layer. The structure can include a back support on the back contact metal. The structure can include a cadmium sulfide layer between the transparent conductive oxide layer and the buffer layer.

In one aspect, a method of manufacturing a structure can include forming a transparent conductive oxide layer adjacent to a substrate and forming a buffer layer adjacent to the transparent conductive oxide layer. The transparent conductive oxide layer can include cadmium and tin. The buffer layer can include zinc and tin. Forming a buffer layer can include sputtering the buffer layer in the presence of an oxygen gas. Forming a buffer layer can include sputtering the buffer layer in the presence of an argon gas. Forming a buffer layer can include sputtering the buffer layer in the presence of an oxygen-argon gas mix. The buffer layer can include a zinc tin oxide. The transparent conductive oxide layer can include a cadmium stannate.

The method can include forming a barrier layer between the substrate and the transparent conductive oxide layer. The barrier layer can include silicon oxide, aluminum-doped silicon oxide, boron-doped silicon oxide, phosphorous-doped silicon oxide, silicon nitride, aluminum-doped silicon nitride, boron-doped silicon nitride, phosphorous-doped silicon nitride, silicon oxide-nitride, titanium oxide, niobium oxide, tantalum oxide, aluminum oxide, zirconium oxide, or tin oxide.

The method can include forming one or more barrier layers adjacent to the substrate (which can include soda-lime glass) and forming the transparent conductive oxide layer on the one or more barrier layers. Each of the one or more barrier layers can include silicon oxide, aluminum-doped silicon oxide, boron-doped silicon oxide, phosphorous-doped silicon oxide, silicon nitride, aluminum-doped silicon nitride, boron-doped silicon nitride, phosphorous-doped silicon nitride, silicon oxide-nitride, titanium oxide, niobium oxide, tantalum oxide, aluminum oxide, zirconium oxide, or tin oxide. The transparent conductive oxide layer can include a cadmium stannate. The method can include forming the buffer layer on the transparent conductive oxide layer. The buffer layer can include a zinc tin oxide with a tin content of about 15%, and a thickness of about 250 to about 1000 A.

The method can include the step of annealing the substrate after the step of forming the buffer layer. The annealing can include heating the substrate to temperature in a range of about 500 to about 700 C. The temperature can be in the range of about 550 to about 650 C. The temperature can be about 600 C. The method can include the step of forming a semiconductor window layer adjacent to the buffer layer. The semiconductor window layer can include cadmium sulfide. The step of forming the semiconductor window layer can include sputtering. The method can include the step of forming a semiconductor absorber layer adjacent to the semiconductor window layer. The semiconductor absorber layer can include cadmium telluride. The method can include forming a back contact metal on the semiconductor absorber layer. The method can include forming a back support on the back contact metal. The method can include forming a cadmium sulfide layer between the transparent conductive oxide layer and the buffer layer.

In one aspect, a sputter target can include a sputter material including zinc and tin having a zinc:tin ratio of between about 19:1 and about 7:3 and a backing tube. The sputter material can be connected to the backing tube to form a sputter target. The sputter target can include a bonding layer bonding the sputter material and the backing tube. The backing tube can include stainless steel. The sputter target can be configured to use in reactive sputtering process.

A method of manufacturing a rotary sputter target can include the steps of forming a sputter material including zinc and tin having a zinc:tin ratio of between about 19:1 and about 7:3 and attaching the sputter material to a backing tube to form a sputter target. The step of attaching the sputter material to a backing tube to form a sputter target can include a thermal spray forming process. The step of attaching the sputter material to a backing tube to form a sputter target can include a plasma spray forming process. The step of attaching the sputter material to a backing tube to form a spatter target can include a powder metallurgy process. The powder metallurgy can include hot press process. The powder metallurgy can include an isostatic process. The step of attaching the sputter material to a backing tube to form a sputter target can include a flow forming process. The step of attaching the sputter material to the backing tube can include bonding the sputtering material to the backing tube with a bonding layer.

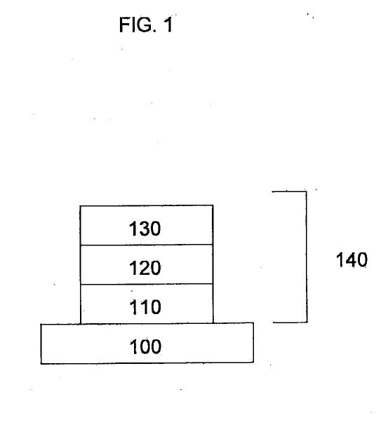

Referring to FIG. 1, a transparent conductive oxide stack 140 can be deposited on a substrate 100. Substrate 100 can include any suitable substrate material, including glass, for example, soda-lime glass. Transparent conductive oxide stack 140 can include a barrier layer 110, which can include any suitable barrier material. Barrier layer 110 can be incorporated between substrate 100 and the TCO layer 120 to lessen diffusion of sodium or other contaminants from the substrate to the semiconductor layers, which could result in poor performance and degradation of the photovoltaic devices. Barrier layer 110 can be transparent, thermally stable, with a reduced number of pin holes and having high sodium blocking capability, and good adhesive properties.

Barrier layer 110 can include a variety of materials such as, by way of example, silicon oxide, aluminum-doped silicon oxide, boron-doped silicon oxide, phosphorous-doped silicon oxide, silicon nitride, aluminum-doped silicon nitride, boron-doped silicon nitride, phosphorous-doped silicon nitride, silicon oxide-nitride, titanium oxide, niobium oxide, tantalum oxide, aluminum oxide, zirconium oxide, tin oxide, or combinations thereof. The dopant can be less than 25%, less than 20%, less than 15%, less than 10%, less than 5% or less than 2%. A barrier layer may also include a high optical index material layer to supplement a low index material layer for the benefits of color suppression and reduction in optical reflection loss. The high index layer may include silicon nitride, aluminum-doped silicon nitride, boron-doped silicon nitride, phosphorous-doped silicon nitride, silicon oxide-nitride, titanium oxide, niobium oxide, tantalum oxide, aluminum oxide, zirconium oxide, or tin oxide. The TCO stack may include multiple barrier materials. For example, the TCO stack can include a compound barrier layer, including a silicon oxide deposited over a high index optical material. The compound barrier layer can be optimized using optical modeling to achieve both color suppression and reduced reflection loss, though in practice a thicker compound layer may be needed to block sodium more effectively.

Because glass is not conductive, a transparent conductive oxide (TCO) layer 120 can be deposited between the substrate 100 and the semiconductor layer. Cadmium stannate functions well in this capacity, as it exhibits both high optical transmission and low electrical sheet resistance. Transparent conductive oxide layer 120 can be deposited adjacent to barrier layer 110. Transparent conductive oxide layer 120 can include a layer of cadmium and tin, and can be of any suitable thickness. For example, transparent conductive oxide layer 120 can have a thickness of about 100 nm to about 1000 nm. Transparent conductive oxide layer 120 can be deposited using any known deposition technique, including sputtering.

Transparent conductive oxide stack 140 can be manufactured using a variety of deposition techniques, including, for example, low pressure chemical vapor deposition, atmospheric pressure chemical vapor deposition, plasma-enhanced chemical vapor deposition, thermal chemical vapor deposition, DC or AC sputtering, spin-on deposition, or spray-pyrolysis. Each deposition layer can be of any suitable thickness, for example, in the range of about 10 to about 5000 A.

A sputtering target can be manufactured by ingot metallurgy. A sputtering target can be manufactured from cadmium, tin, silicon, or aluminum, or combinations or alloys thereof suitable to make individual layers in the stack. For example, the target for barrier layer can be Si₈₅Al₁₅. The targets for making cadmium stannate layer can be a cadmium and tin alloy in stoichiometrically proper amounts. A sputtering target can be manufactured as a single piece in any suitable shape. A sputtering target can be a tube. A sputtering target can be manufactured by casting a metallic material into any suitable shape, such as a tube.

A sputtering target can be manufactured from more than one piece. A sputtering target can be manufactured from more than one piece of metal, for example, a piece of cadmium and a piece of tin. The cadmium and tin can be manufactured in any suitable shape, such as sleeves, and can be joined or connected in any suitable manner or configuration. For example, apiece of cadmium and a piece of tin can be welded together to form the sputtering target. One sleeve can be positioned within another sleeve.

A sputtering target can be manufactured by powder metallurgy. A sputtering target can be formed by consolidating metallic powder (e.g., cadmium or tin powder) to form the target. The metallic powder can be consolidated in any suitable process (e.g., pressing such as isostatic pressing) and in any suitable shape. The consolidating can occur at any suitable temperature. A sputtering target can be formed from metallic powder including more than one metal powder (e.g., cadmium and tin). More than one metallic powder can be present in stoichiometrically proper amounts.

A sputter target can be manufactured by positioning wire including target material adjacent to a base. For example wire including target material can be wrapped around a base tube. The wire can include multiple metals (e.g., cadmium and tin) present in stoichiometrically proper amounts. The base tube can be formed from a material that will not be sputtered. The wire can be pressed (e.g., by isostatic pressing).

A sputter target can be manufactured by spraying a target material onto a base. Metallic target material can be sprayed by any suitable spraying process, including twin wire are spraying and plasma spraying. The metallic target material can include multiple metals (e.g., cadmium and tin), present in stoichiometrically proper amounts. The base onto which the metallic target material is sprayed can be a tube.

Referring again to FIG. 1, a buffer layer 130 can be deposited on transparent conductive oxide layer 120 to become part of transparent conductive oxide stack 140. TCO stack 140 can include, for example, a silicon dioxide barrier layer 110, a cadmium stannate TCO layer 120, and a buffer layer 130. Buffer layer 130 can decrease the likelihood of irregularities occurring during the formation of the semiconductor window layer. Buffer layer 130 can include various suitable materials, including tin oxide, zinc tin oxide, zinc oxide, and zinc magnesium oxide. Buffer layer 130 can include a layer of zinc and tin. For example, buffer layer 130 can include a zinc tin oxide. Buffer layer 130 can include any suitable ratio of tin to zinc. For example, buffer layer 130 can include a tin to zinc ratio in the range of about 1:100 to about 100:1 by weight, for example, about 15:85. Buffer layer 130 can also have any suitable thickness. For example, buffer layer 130 can have a thickness in the range of about 50 to about 2000 A, for example, about 250 to about 1000 A. Buffer layer 130 can be deposited using any suitable means, including sputtering, for example, DC sputtering, AC sputtering, or pulsed DC sputtering. Buffer layer 130 can be sputtered from a zinc:tin alloy target, where the zinc to tin ratio is between about 19:1 and about 7:3. Buffer layer 130 can also be sputtered from a zinc tin oxide ceramic target. Buffer layer 130 can be deposited in the presence of one or more reactive gases, for example, an oxygen gas, an argon gas, and an oxygen-argon gas mix. Buffer layer 130 can be deposited in a substantially amorphous state. A control layer may be deposited on transparent conductive oxide layer 120 to enable proper transformation of transparent conductive oxide layer 120, prior to deposition of buffer layer 130. Or buffer layer 130 may be deposited directly on transparent conductive oxide layer 120.

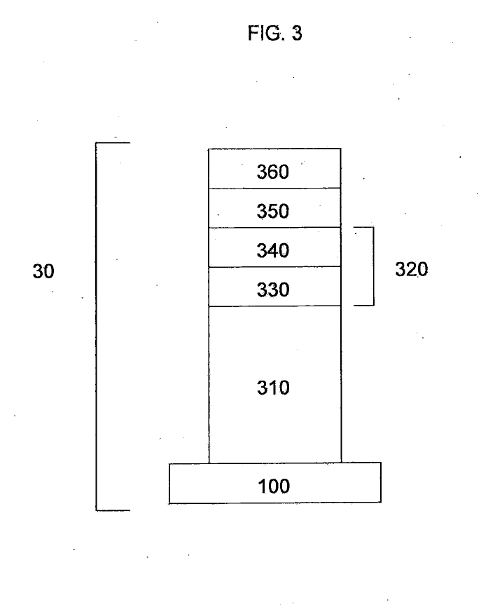

Transparent conductive oxide stack 140 from FIG. 1 can be annealed to form annealed transparent conductive oxide stack 310 from FIG. 3, thereby forming a zinc stannate. Transparent conductive oxide stack 140 can be annealed using any suitable annealing process. The annealing can occur in the presence of a gas selected to control the atmosphere of the annealing, for example, nitrogen gas. The annealing may be aided by providing an oxygen-depleting or oxygen-reducing environment. Transparent conductive oxide stack 140 can be annealed under any suitable pressure, for example, under reduced pressure, in a low vacuum, or at about 0.01 Pa (10⁴ Torr). Transparent conductive oxide stack 140 can be annealed at any suitable temperature or temperature range. For example, transparent conductive oxide stack 140 can be annealed at about 400 to about 800 C. Transparent conductive oxide stack 140 can be annealed at about 500 to about 700 C. Transparent conductive oxide stack 140 can be annealed at about 550 to about 650 C. Transparent conductive oxide stack 140 can be annealed for any suitable duration. For example, transparent conductive oxide stack 140 can be annealed for more than about 5 minutes. Transparent conductive oxide stack 140 can be annealed for about 10 to about 25 minutes. Transparent conductive oxide stack 140 can be annealed for about 15 to about 20 minutes.

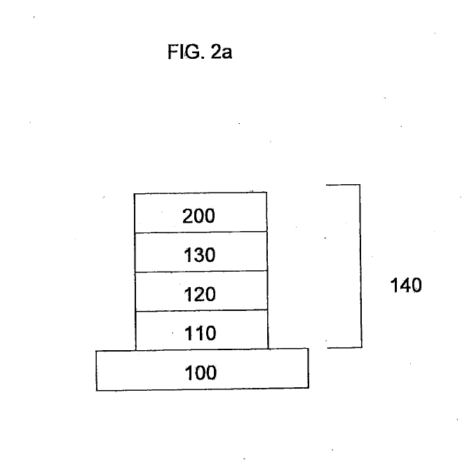

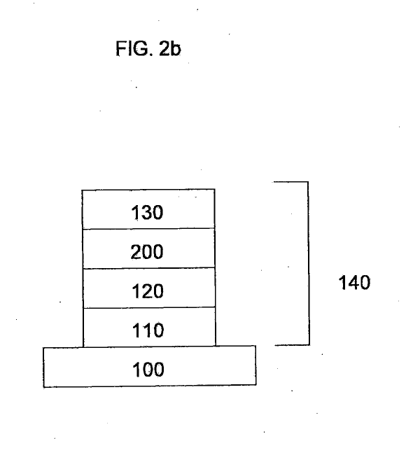

Prior to annealing, a cadmium sulfide layer can be deposited adjacent to buffer layer 130 to become part of transparent conductive oxide stack 140. The cadmium sulfide layer may aid the annealing process by providing a suitable ambient condition for converting the transparent conductive oxide stack 140. The cadmium layer may be partially or completely consumed during the annealing process (as a result of evaporation and/or diffusion) so as to provide a suitable annealing environment for acquiring optimum optical and electrical properties. Referring to FIGS. 2a and 2b, by way of example, cadmium sulfide layer 200 can be deposited on buffer layer 130, or between transparent conductive oxide layer 120 and buffer layer 130. Cadmium sulfide layer 200 can be placed directly on transparent conductive oxide layer 120 or buffer layer 130, or an intervening layer can be placed in between. Cadmium sulfide layer 200 can have any suitable thickness, including about 50 to about 500 A. Preferably, the thickness of the cadmium sulfide layer is such that the layer is mostly or completely consumed during the annealing process. Transparent conductive oxide stack 140 can be annealed including cadmium sulfide layer 200, or absent cadmium sulfide layer 200.

Referring to FIG. 3, annealed transparent conductive oxide stack 310 can be used to form photovoltaic device 30. A semiconductor layer 320 can be deposited adjacent to annealed transparent conductive oxide stack 310. Semiconductor layer 320 can include a semiconductor window layer 330 and a semiconductor absorber layer 340. Semiconductor window layer 330 can include any suitable material, such as a cadmium sulfide layer, which can include any suitable thickness, including about 50 to about 1500 A. Semiconductor window layer 330 can be deposited adjacent to annealed transparent conductive oxide stack 310. Semiconductor window layer 330 can be deposited using any known deposition technique, including, for example, chemical bath deposition, closed space sublimation, vapor transport deposition, and sputtering. Semiconductor absorber layer 340 can be deposited adjacent to semiconductor window layer 330. Semiconductor absorber layer 340 can be deposited using any known deposition technique, including vapor transport deposition. Semiconductor absorber layer 340 can include any suitable material, such as a cadmium telluride layer. A back contact 350 can be deposited adjacent to semiconductor layer 320. Back contact 350 can be deposited adjacent to semiconductor absorber layer 340. Back contact 350 can contain any suitable metal or alloy. A back support 360 can be deposited adjacent to back contact 250. Back support 360 can include a glass, for example, a soda-lime glass. The glass may include a soda-lime glass with reduced iron content.

Photovoltaic devices/modules fabricated using the methods and apparatuses discussed herein may be incorporated into one or more photovoltaic arrays. The arrays may be incorporated into various systems for generating electricity. For example, a photovoltaic module may be illuminated with a beam of light to generate a photocurrent. The photocurrent may be collected and converted from direct current (DC) to alternating current (AC) and distributed to a power grid. Light of any suitable wavelength may be directed at the module to produce the photocurrent, including, for example, more than 400 nm, or less than 700 nm (e.g., ultraviolet light). Photocurrent generated from one photovoltaic module may be combined with photocurrent generated from other photovoltaic modules. For example, the photovoltaic modules may be part of a photovoltaic array, from which the aggregate current may be harnessed and distributed.

The embodiments described above are offered by way of illustration and example. It should be understood that the examples provided above may be altered in certain respects and still remain within the scope of the claims. It should be appreciated that, while the invention has been described with reference to the above preferred embodiments, other embodiments are within the scope of the claims.

1. A structure comprising:
a substrate;
a transparent conductive oxide layer adjacent to the substrate, wherein the transparent conductive oxide layer comprises cadmium and tin; and
a buffer layer adjacent to the transparent conductive oxide layer, wherein the buffer layer comprises zinc and tin.

2. The structure of claim 1, wherein the buffer layer has a thickness of about 50 Á to about 2000 Á.

3. The structure of claim 1, wherein the buffer layer has a tin to zinc ratio that ranges from about 1:100 to about 100:1 by weight.

4. The structure of claim 1, wherein the buffer layer comprises a zinc tin oxide or a zinc stannate.

5. The structure of claim 1, wherein the transparent conductive oxide layer comprises a cadmium stannate.

6. The structure of claim 1, wherein the substrate comprises a glass.

7. The structure of claim 1, further comprising
one or more barrier layers on a soda-lime glass substrate, wherein the transparent conductive oxide layer is positioned on the one or more barrier layers, wherein each of the one or more barrier layers comprises a material selected from the group consisting of silicon oxide, aluminum-doped silicon oxide, boron-doped silicon oxide, phosphorous-doped silicon oxide, silicon nitride, aluminum-doped silicon nitride, boron-doped silicon nitride, phosphorous-doped silicon nitride, silicon oxide-nitride, titanium oxide, niobium oxide, tantalum oxide, aluminum oxide, zirconium oxide, and tin oxide, wherein the transparent conductive oxide layer comprises a cadmium stannate, and the buffer layer comprises a zinc tin oxide.

8. The structure of claim 7, further comprising a semiconductor window layer adjacent to the buffer layer, wherein the semiconductor window layer comprises cadmium sulfide.

9. The structure of claim 8, wherein the semiconductor window layer has a thickness of about 50 ̂ A to about 500 ̂ A.

10. The structure of claim 8, further comprising a semiconductor absorber layer adjacent to the semiconductor window layer, wherein the semiconductor absorber layer comprises cadmium telluride.

11. The structure of claim 1, further comprising a cadmium sulfide layer between the transparent conductive oxide layer and the buffer layer.

12. A method of manufacturing a structure, comprising:
forming a transparent conductive oxide layer adjacent to a substrate, wherein the transparent conductive oxide layer comprises cadmium and tin; and
forming a buffer layer adjacent to the transparent conductive oxide layer, wherein the buffer layer comprises zinc and tin.

13. The method of claim 12, wherein forming a buffer layer comprises sputtering the buffer layer in the presence of an oxygen gas, argon gas, or an oxygen-argon gas mix.

14. The method of claim 12, further comprising
forming one or more barrier layers adjacent to the substrate, wherein the substrate comprises soda-lime glass;
forming the transparent conductive oxide layer on the one or more barrier layers, wherein each of the one or more barrier layers comprises a material selected from the group consisting of silicon oxide, aluminum-doped silicon oxide, boron-doped silicon oxide, phosphorous-doped silicon oxide, silicon nitride, aluminum-doped silicon nitride, boron-doped silicon nitride, phosphorous-doped silicon nitride, silicon oxide-nitride, titanium oxide, niobium oxide, tantalum oxide, aluminum oxide, zirconium oxide, and tin oxide, and wherein the transparent conductive oxide layer comprises a cadmium stannate; and
forming the buffer layer on the transparent conductive oxide layer, wherein the buffer layer comprises a zinc tin oxide with a tin content of about 15%, and a thickness of about 250 Á to about 1000 Á.

15. The method of claim 12, further comprising the step of annealing the substrate after the step of forming the buffer layer.

16. The method of claim 15, wherein the annealing comprises heating the substrate to temperature in a range of about 500° C. to about 700° C.

17. The method of claim 12, further comprising the step of forming a semiconductor window layer adjacent to the buffer layer, wherein the semiconductor window layer comprises cadmium sulfide.

18. The method of claim 17, wherein the step of forming the semiconductor window layer comprises sputtering.

19. The method of claim 17, further comprising the step of forming a semiconductor absorber layer adjacent to the semiconductor window layer, wherein the semiconductor absorber layer comprises cadmium telluride.

20. The method of claim 12, further comprising forming a cadmium sulfide layer between the transparent conductive oxide layer and the buffer layer.

21-27. (canceled)
